(19) United States
(12) Patent Application Publication
(10) Pub. No.: US 2021/0210540 A1
(43) Pub. Date: Jul. 8, 2021

(54) IMAGING ELEMENT AND METHOD OF MANUFACTURING IMAGING ELEMENT

(71) Applicant: SONY SEMICONDUCTOR SOLUTIONS CORPORATION, KANAGAWA (JP)

(72) Inventor: HIROTAKA KOBAYASHI, TOKYO (JP)

(21) Appl. No.: 17/250,730

(22) PCT Filed: Aug. 9, 2019
(86) PCT No.: PCT/JP2019/031553

§ 371 Date: Feb. 25, 2021

(30) Foreign Application Priority Data
Sep. 7, 2018 (JP) 2018-167600

(51) Int. Cl. H01L 27/146

(52) U.S. Cl. CPC H01L 27/14632; H01L 27/14687; H01L 27/14627; H01L 27/14618

(57) ABSTRACT

A method of manufacturing an imaging element having a light receiving surface curved in accordance with an aberration of an imaging lens is simplified. The imaging element includes an imaging chip, a curve forming portion, and a curve holding portion. The imaging chip includes a semiconductor chip having a rear surface on which a concave portion is formed, the rear surface being a surface different from a light receiving surface that receives light from a subject. The curve forming portion is arranged in the concave portion and forms a curved portion by curving the imaging chip at a bottom of the concave portion. The curve holding portion holds the formed curved portion.

### TECHNICAL FIELD

The present disclosure relates to an imaging element and a method of manufacturing the imaging element. More specifically, the present disclosure relates to an imaging element having a curved light receiving surface and a method of manufacturing the imaging element.

### BACKGROUND ART

A solid-state imaging device accommodating a solid-state imaging element that images a subject formed as an image by an imaging lens has been used in the related art. There is an aberration in an imaging lens, and when a subject is formed as an image on a flat solid-state imaging element, blurring occurs at a central portion or an end portion of the solid-state imaging element. Therefore, an imaging device that prevents the occurrence of blurring at a central portion or an end portion of a solid-state imaging element by curving the solid-state imaging element in accordance with an aberration of an imaging lens has been proposed. For example, a solid-state imaging device including a plate-like semiconductor substrate having a first surface which is a surface on which a solid-state imaging element is formed and a second surface which is a rear surface of the first surface, and a resin layer having a flat third surface and a fourth surface which is a rear surface of the third surface and has a curved concave portion formed thereon has been proposed. In the solid-state imaging device, the second surface of the semiconductor substrate and the third surface of the resin layer are adhered to each other, and then the fourth surface of the resin layer is adhered to a package. At this time, concave portions can be formed on the first surface and the second surface of the solid-state imaging device by deforming the resin layer in accordance with a shape of the concave portion of the fourth surface by also closely adhering the concave portion of the fourth surface of the resin layer to the package (for example, see Patent Document 1).

### CITATION LIST

### Patent Document

Patent Document 1: Japanese Patent Application Laid-Open No. 2015-192074

### SUMMARY OF THE INVENTION

### Problems to be Solved by the Invention

In the conventional technology described above, when the fourth surface of the resin layer on which the concave portion is formed is closely adhered to the package, air in a region surrounded by the concave portion of the fourth surface and the package is exhausted through a through-hole formed in the package. An atmospheric pressure is applied to the semiconductor substrate by this step to form the curved concave portion. As such, in the conventional technology described above, the step of exhausting the air in the package is required, and thus, a manufacturing process of the imaging device is complicated.

The present disclosure has been made in view of the problems described above, and an object of the present disclosure is to simplify a method of manufacturing an imaging element having a light receiving surface curved in accordance with an aberration of an imaging lens.

### Solution to Problems

The present disclosure is made in order to solve the problems described above, and a first aspect of the present disclosure is an imaging element including: an imaging chip that includes a semiconductor chip having a rear surface on which a concave portion is formed, the rear surface being a surface different from a light receiving surface that receives light from a subject; a curve forming portion that is arranged in the concave portion and forms a curved portion by curving the imaging chip at a bottom of the concave portion; and a curve holding portion that holds the formed curved portion.

Furthermore, in the first aspect, the curve forming portion may have a linear expansion coefficient higher than that of the imaging chip and may be heated to form the curved portion.

Furthermore, in the first aspect, the curve forming portion may include a metal.

Furthermore, in the first aspect, the curve holding portion may include a thermosetting resin.

Furthermore, in the first aspect, the curve forming portion may form the curved portion when the curve holding portion is cured.

Furthermore, in the first aspect, the curve holding portion may include a thermosetting resin that shrinks when cured.

Furthermore, in the first aspect, the imaging element may further include a lid that is arranged to be adjacent to the curve holding portion and limits shrinkage of the curve holding portion in the vicinity of an opening of the concave portion.

The curve holding portion may include a holding base body in which a second concave portion fitted into the curved portion is arranged and an adhesive portion arranged between the holding base body and the curve forming portion.

Furthermore, in the first aspect, the imaging element may further include an etching prevention layer that is arranged at a bottom of the concave portion in the semiconductor chip and prevents etching of the semiconductor chip.

Furthermore, a second aspect of the present disclosure is a method of manufacturing an imaging element, the method including: a step of forming a concave portion on a rear surface of an imaging chip that includes a semiconductor chip, the rear surface being a surface different from a light receiving surface that receives light from a subject; a step of forming a curved portion by a curve forming portion that forms the curved portion by curving the imaging chip at a bottom of the concave portion; and a step of holding the curved portion by a curve holding portion that holds the formed curved portion.

By adopting the aspects described above, the curve forming portion and the curve holding portion are arranged in the vicinity of the bottom of the concave portion formed on the rear surface of the imaging chip, which causes an action of holding the imaging chip in a curved state in a rear direction. It is expected to simplify the formation of the curved portion on the light receiving surface of the imaging chip.

### Effects of the Invention

According to the present disclosure, an excellent effect of simplifying the method of manufacturing the imaging element having the light receiving surface curved in accordance with the aberration of the imaging lens is achieved.

### BRIEF DESCRIPTION OF DRAWINGS

FIG. 1 is a block diagram illustrating a configuration example of an imaging element according to an embodiment of the present disclosure.

FIG. 2 is a view illustrating a configuration example of the imaging element according to the embodiment of the present disclosure.

FIG. 3 is a cross-sectional view illustrating a configuration example of an imaging element according to a first embodiment of the present disclosure.

FIG. 4 is a cross-sectional view illustrating another configuration example of the imaging element according to the first embodiment of the present disclosure.

FIG. 5 is a cross-sectional view illustrating a configuration example of an imaging device according to the first embodiment of the present disclosure.

FIG. 6 is a view illustrating an example of a curve according to the first embodiment of the present disclosure.

FIG. 7 is a view illustrating an example of a method of manufacturing the imaging element according to the first embodiment of the present disclosure.

FIG. 8 is a view illustrating an example of the method of manufacturing the imaging element according to the first embodiment of the present disclosure.

FIG. 9 is a cross-sectional view illustrating a configuration example of an imaging element according to a second embodiment of the present disclosure.

FIG. 10 is a cross-sectional view illustrating a configuration example of an imaging element according to a third embodiment of the present disclosure.

FIG. 11 is a cross-sectional view illustrating a configuration example of an imaging element according to a fourth embodiment of the present disclosure.

FIG. 12 is a cross-sectional view illustrating another configuration example of the imaging element according to the fourth embodiment of the present disclosure.

FIG. 13 is a cross-sectional view illustrating a configuration example of an imaging element according to a fifth embodiment of the present disclosure.

FIG. 14 is a cross-sectional view illustrating a configuration example of an imaging element according to a sixth embodiment of the present disclosure.

FIG. 15 is a cross-sectional view illustrating a configuration example of an imaging element according to a seventh embodiment of the present disclosure.

### MODE FOR CARRYING OUT THE INVENTION

Next, modes for carrying out the present disclosure (hereinafter, referred to as embodiments) will be described with reference to the drawings. In the following drawings, the same or similar portions are denoted by the same or similar reference numerals. However, the drawings are schematic, and ratios of dimensions and the like of each of the portions may not necessarily coincide with actual ones. Furthermore, portions having relationships or ratios of dimensions different from each other are included in the drawings, as a matter of course. Furthermore, the embodiments will be described in the following order.

1. First Embodiment

2. Second Embodiment

3. Third Embodiment

4. Fourth Embodiment

5. Fifth Embodiment

6. Sixth Embodiment

7. Seventh Embodiment

### 1. First Embodiment

[Configuration of Imaging Element]

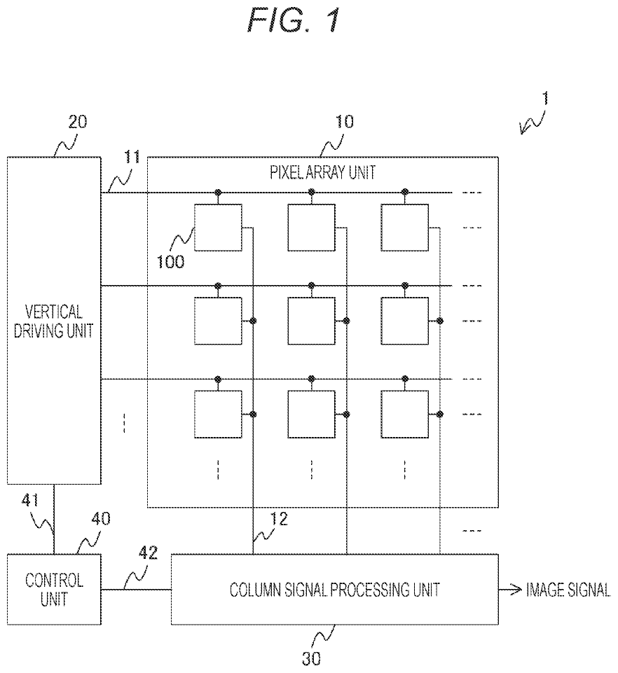

FIG. 1 is a block diagram illustrating a configuration example of an imaging element according to an embodiment of the present disclosure. An imaging element 1 in FIG. 1 includes a pixel array unit 10, a vertical driving unit 20, a column signal processing unit 30, and a control unit 40.

The pixel array unit 10 is configured by arranging pixels 100 in a two-dimensional grid shape. Here, the pixel 100 generates an image signal according to irradiated light. The pixel 100 includes a photoelectric conversion unit that generates a charge according to the irradiated light. In addition, the pixel 100 further includes a pixel circuit. The pixel circuit generates an image signal on the basis of the charge generated by the photoelectric conversion unit. The generation of the image signal is controlled by a control signal generated by a vertical driving unit 20 as described later. Signal lines 11 and 12 are arranged in the pixel array unit 10 in an XY matrix shape. The signal line 11 is a signal line that transmits the control signal of the pixel circuit in the pixel 100, is arranged for each row of the pixel array unit 10, and is commonly wired to the pixels 100 arranged in each row. The signal line 12 is a signal line that transmits the image signal generated by the pixel circuit of the pixel 100, is arranged for each column of the pixel array unit 10, and is commonly wired to the pixels 100 arranged in each column. The photoelectric conversion unit and the pixel circuit are formed on a semiconductor substrate 111 and a wiring region 121 as described later.

The vertical driving unit 20 generates the control signal of the pixel circuit of the pixel 100. The vertical driving unit 20 transmits the generated control signal through the signal line 11 in FIG. 1 to the pixel 100. The column signal processing unit 30 processes the image signal generated by the pixel 100. The column signal processing unit 30 performs processing of the image signal transmitted from the pixel 100 through the signal line 12 in FIG. 1. The processing in the column signal processing unit 30 corresponds to, for example, analog-digital conversion that converts an analog image signal generated in the pixel 100 to a digital image signal. The image signal processed by the column signal processing unit 30 is output as an image signal of the imaging element 1. The control unit 40 controls the entire imaging element 1. The control unit 40 controls the imaging element 1 by generating and outputting a control signal that controls the vertical driving unit 20 and the column signal processing unit 30. The control signals generated by the control unit 40 are transmitted to the vertical driving unit 20 and the column signal processing unit 30 through signal lines 41 and 42, respectively.

[Appearance of Imaging Element]

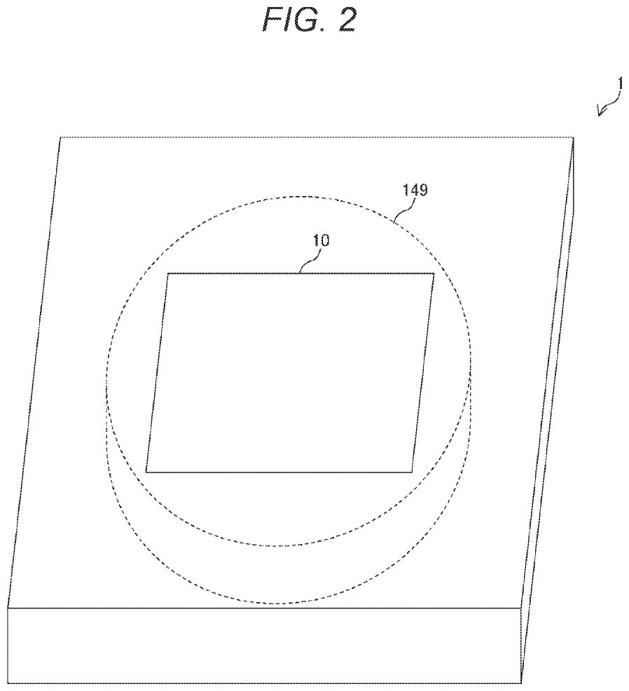

FIG. 2 is a view illustrating a configuration example of the imaging element according to the embodiment of the present disclosure. FIG. 2 is an appearance view illustrating a configuration example of the imaging element 1. In the imaging element 1 in FIG. 2, the pixel array unit 10 illustrated in FIG. 1 is formed on a light receiving surface which is a surface that receives light from a subject. Furthermore, a columnar concave portion 149 is formed on a rear surface which is a surface different from the light receiving surface. As described later, a bottom surface of the concave portion 149 is curved in a rear surface direction in FIG. 2, and the pixel array unit 10 is also curved along the curve thereof. Therefore, it is possible to prevent deterioration of image quality based on an aberration of an imaging lens.

Note that a shape of the concave portion 149 is not limited to the example. For example, the concave portion 149 can be formed in a shape of a rectangular prism or octagonal prism.

[Configuration of Cross Section of Imaging Element]

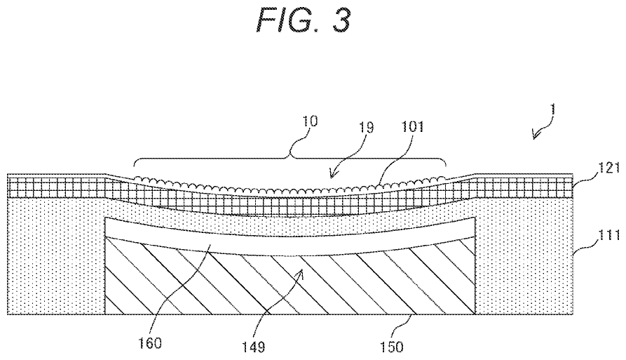

FIG. 3 is a cross-sectional view illustrating a configuration example of an imaging element according to a first embodiment of the present disclosure. The imaging element 1 in FIG. 3 includes a semiconductor substrate 111, a wiring region 121, a curve forming portion 160, and a curve holding portion 150.

The semiconductor substrate 111 is a substrate of a semiconductor on which a part of a semiconductor element of the pixel array unit 10 is formed. The semiconductor substrate 111 can include, for example, silicon. The photoelectric conversion unit or the pixel circuit, the vertical driving unit 20, and the like illustrated in FIG. 1 are formed on the semiconductor substrate 111. The wiring region 121 is formed on a front surface of the semiconductor substrate 111, and a color filter or an on-chip lens (not illustrated) is arranged on a front surface of the wiring region 121. The color filter is an optical filter through which light of a predetermined wavelength among incident light is transmitted, and the on-chip lens is a lens that is arranged on each pixel 100 and concentrates incident light. The imaging element 1 in FIG. 3 corresponds to a front surface irradiation type imaging element in which the pixel 100 is irradiated with incident light from the front surface of the semiconductor substrate 111.

Furthermore, the concave portion 149 illustrated in FIG. 2 is arranged on a rear surface of the semiconductor substrate 111. The concave portion 149 can be formed by, for example, etching the semiconductor substrate 111.

The wiring region 121 is a region in which wires transmitting a signal are formed. The wiring region includes a wiring layer in which wires are formed and an insulating layer insulating the wires. The signal lines 11, 12, 41, and 42 illustrated in FIG. 1 are arranged in the wiring region 121. The insulating layer can include, for example, a metal such as copper (Cu), aluminum (Al), or the like. Furthermore, the insulating layer can include, for example, silicon oxide (SiO₂).

As illustrated in FIG. 3, a curved portion 19 curved in a rear direction is arranged on the semiconductor substrate 111 and the wiring region 121. Note that the semiconductor substrate 111 and the wiring region 121 configure an imaging chip.

The curve forming portion 160 is arranged in the concave portion 149, and forms the curved portion 19 by curving the semiconductor substrate 111 and the wiring region 121. The curve forming portion 160 can include a material having a linear expansion coefficient higher than that of the semiconductor substrate 111 or the wiring region 121. As described above, in a case where the semiconductor substrate 111 includes silicon (Si) and the wiring region 121 includes the insulating layer including SiO₂ and the wiring layer including Cu or Al, a metal can be used as the curve forming portion 160. For example, Cu, Al, gold (Au), platinum (Pt), titanium (Ti), nickel (Ni), and tantalum (Ta) can be used as the curve forming portion 160.

The curve forming portion 160 is arranged, and then, the semiconductor substrate 111, the wiring region 121, and the curve forming portion 160 are heated and expanded. At this time, a linear expansion coefficient of the curve forming portion 160 is higher than those of the semiconductor substrate 111 and the wiring region 121. Therefore, as illustrated in FIG. 3, the semiconductor substrate 111 and the wiring region 121 can be curved in the rear surface direction. Furthermore, strength of the imaging chip in which the concave portion 149 is formed can be enhanced by arranging the curve forming portion 160.

The curve holding portion 150 holds the curved portion 19. The curve holding portion 150 is arranged in the concave portion 149 in which the curved portion 19 is formed, and can include, for example, a resin. The curve holding portion 150 is adhered to the semiconductor substrate 111 and the wiring region 121, such that the curved portion 19 can be held while maintaining a curved state. A photocurable resin or a thermosetting resin can be used for the curve holding portion 150. Note that the curve holding portion 150 preferably includes a thermosetting resin. This is because the curved portion 19 can be formed by the curve forming portion 160 through heating performed when the curve holding portion 150 is cured. Specifically, a liquid curve holding portion 150 is arranged in the concave portion 149, and the imaging chip, the curve forming portion 160, and the curve holding portion 150 are heated to a curing temperature of the curve holding portion 150. The curve forming portion 160 is expanded by the heating and the curved portion 19 is thus formed. Thereafter, the curve holding portion 150 is cured. Since the curve holding portion 150 is cured, the curved portion 19 can be held even though a temperature of the imaging chip returns to room temperature. Note that the curve forming portion 160 described above can form the curved portion 19 when at least a part of the curve holding portion 150 is cured.

Furthermore, a resin that shrinks when cured can be used for the curve holding portion 150. In this case, the curved portion 19 can be formed by shrinkage of the curve holding portion 150 in addition to the curve forming portion 160.

[Another Configuration of Cross Section of Imaging Element]

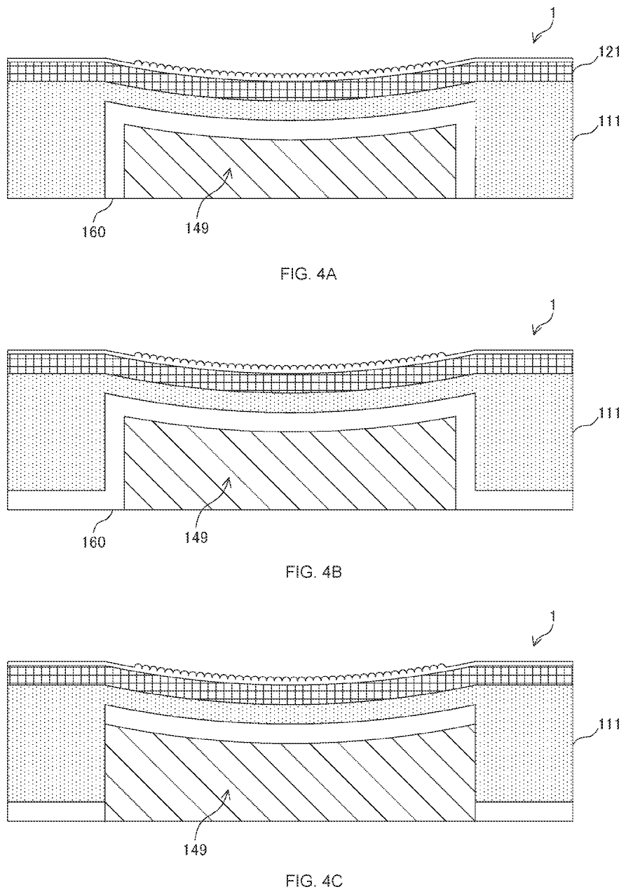

FIG. 4 is a cross-sectional view illustrating another configuration example of the imaging element according to the first embodiment of the present disclosure. a in FIG. 4 illustrates an example in which the curve forming portion 160 is arranged on the bottom surface and side surfaces of the concave portion 149. b in FIG. 4 illustrates an example in which the curve forming portion 160 is arranged on the bottom surface and the side surfaces of the concave portion 149 and the rear surface of the semiconductor substrate 111. c in FIG. 4 illustrates an example in which the curve forming portion 160 is arranged on the bottom surface of the concave portion 149 and the rear surface of the semiconductor substrate 111.

[Configuration of Imaging Device]

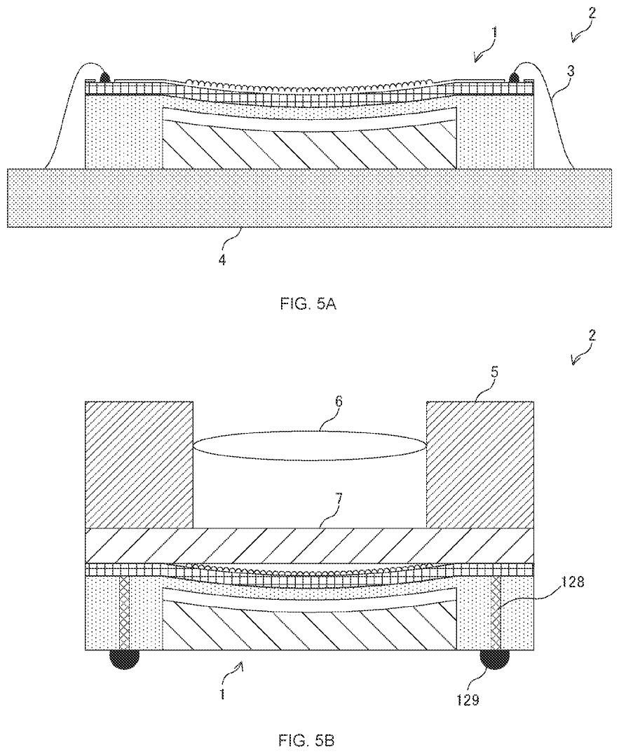

FIG. 5 is a cross-sectional view illustrating a configuration example of an imaging device according to the first embodiment of the present disclosure. a in FIG. 5 illustrates an example in which the imaging element 1 is mounted on a circuit board 4. The imaging element 1 is die-bonded to the circuit board 4, and the imaging element 1 and the circuit board 4 are electrically connected to each other by a bonding wire 3. A pad (not illustrated) to which the bonding wire 3 is connected is arranged on the imaging element 1. The pad is arranged at a peripheral edge of the imaging element 1. The region is a region outside the curved portion 19, and is thus a region parallel to a mounting surface of the circuit board 4. Therefore, wire bonding can be performed without being affected by the curved portion 19.

b in FIG. 5 illustrates an example of an imaging module in which an imaging lens 6 and an actuator 5 are arranged and which is configured in chip size package (CSP). The actuator 5 drives the imaging lens 6. The actuator 5 is arranged on the imaging element 1 with a protective glass 7 interposed between the actuator 5 and the imaging element 1. Since the curved portion 19 is arranged on the light receiving surface of the imaging element 1, a spacer can be omitted, and the protective glass 7 and the imaging element 1 can be directly adhered to each other by an adhesive or the like. Note that a spacer can be arranged between the protective glass 7 and the imaging element 1. A solder bump 129 is arranged on the rear surface of the imaging element 1. The wiring region 121 and the solder bump 129 are connected to each other by a via 128.

[Amount of Curve]

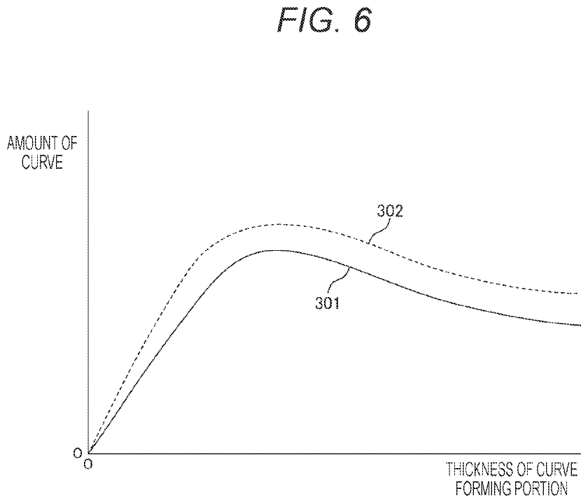

FIG. 6 is a view illustrating an example of a curve according to the first embodiment of the present disclosure. FIG. 6 is a view illustrating a relationship between a thickness and an amount of curve of the curve forming portion 160. Here, the amount of curve represents a maximum value of the amount of warp of the curved portion 19 on the light receiving surface based on a front surface of the imaging element 1. A solid line graph 301 and a dotted line graph 302 in FIG. 6 are graphs showing the relationship between the thickness and the amount of curve of the curve forming portion 160 in a case where heating temperatures are 160° C. and 200° C., respectively. As illustrated in FIG. 6, the amount of curve can be changed by changing the thickness of the curve forming portion. Furthermore, as illustrated in FIG. 6, maximum values exist in the amounts of curve. Therefore, a curing temperature or the like can be adjusted so that a desired amount of curve is close to the maximum value of the graph, and the amount of curve can be hardly affected by an error of the thickness of the curve forming portion 160.

[Method of Manufacturing Imaging Element]

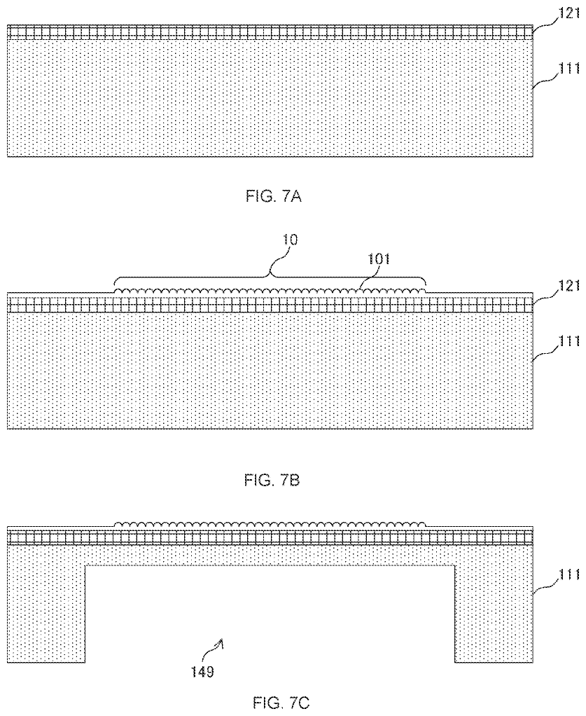

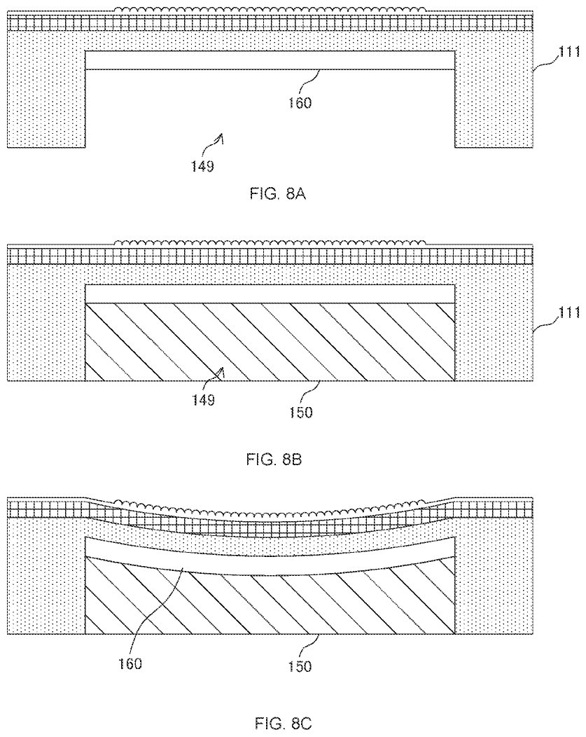

FIGS. 7 and 8 are views each illustrating an example of a method of manufacturing the imaging element according to the first embodiment of the present disclosure. FIGS. 7 and 8 are views each illustrating an example of a manufacturing process of the imaging element 1.

First, a semiconductor element such as a photoelectric conversion unit, a pixel circuit, or the like is formed on the semiconductor substrate 111 to form the wiring region 121 (a in FIG. 7). Next, the color filter (not illustrated) and the on-chip lens 101 are arranged on the front surface of the wiring region 121 (b in FIG. 7).

Next, the concave portion 149 is formed on the rear surface of the semiconductor substrate 111 (c in FIG. 7). This can be performed by etching. Specifically, this can be performed by forming a mask including a resist or the like and having an opening at a position at which the concave portion 149 is arranged on the rear surface of the semiconductor substrate 111, and performing etching by spraying an aqueous solution such as potassium hydroxide or the like. Furthermore, the etching of the semiconductor substrate 111 can be performed by dry etching. This step is an example of a step of forming the concave portion described in the claims.

Next, the curve forming portion 160 is arranged in the concave portion 149 (d in FIG. 8). This can be performed by, for example, sputtering or plating. Next, the curve holding portion 150 is arranged in the concave portion 149 (e in FIG. 8). For example, this can be performed by applying a liquid resin which is a material of the curve holding portion 150 to the concave portion 149 by a dispenser or the like. Note that the applied liquid resin can be held by inverting the top and bottom of the imaging element 1 of e in FIG. 8 and applying a liquid resin thereto.

Next, an imaging element chip is heated. Therefore, the curved portion 19 is formed by the curve forming portion 160. This step is an example of a step of forming the curved portion described in the claims. Thereafter, the curve holding portion 150 is cured to hold the formed curved portion 19 (f in FIG. 8). This step is an example of a step of holding the curved portion described in the claims. The imaging element 1 can be manufactured by the steps described above.

As described above, in the imaging element 1 of the first embodiment of the present disclosure, the curve forming portion 160 having a linear expansion coefficient higher than that of the imaging element chip is arranged in the concave portion 149 of the semiconductor chip and is heated to form the curved portion 19. Thereafter, the formed curved portion 19 is held by the curve holding portion 150. Therefore, the manufacturing process of the imaging element 1 having the curved portion 19 can be simplified.

### 2. Second Embodiment

The imaging element 1 of the first embodiment described above is a front surface irradiation type imaging element. Meanwhile, an imaging element 1 of a second embodiment of the present disclosure is different from that of the first embodiment described above in that the imaging element 1 of the second embodiment is a rear surface irradiation type imaging element.

[Configuration of Cross Section of Imaging Element]

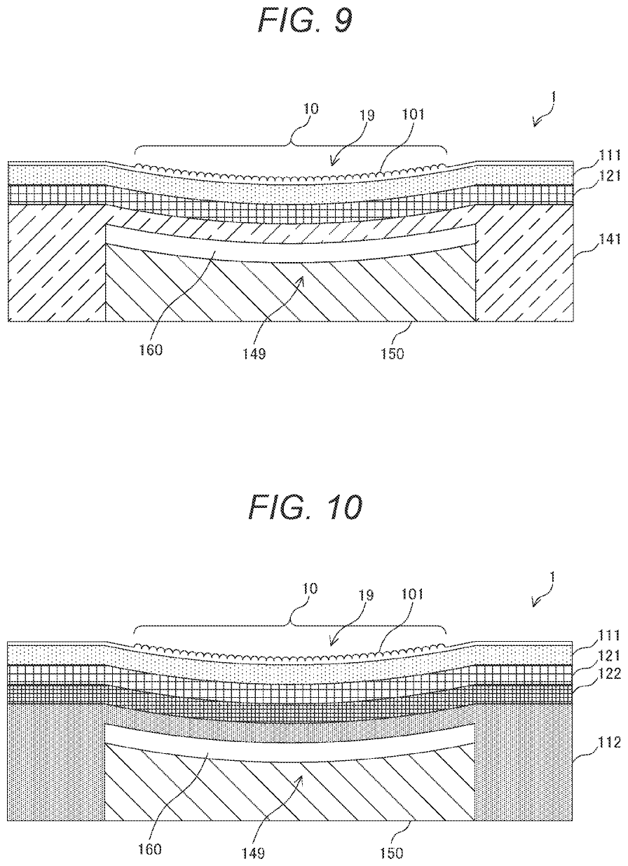

FIG. 9 is a cross-sectional view illustrating a configuration example of the imaging element according to the second embodiment of the present disclosure. The imaging element 1 in FIG. 9 is different from the imaging element 1 illustrated in FIG. 3 in that the imaging element 1 having a configuration in which the semiconductor substrate 111 and the wiring region 121 are replaced is used. That is, in the imaging element 1 in FIG. 9, the wiring region 121 is arranged on the front surface (lower surface in FIG. 9) of the semiconductor substrate 111, and the color filter or the on-chip lens 101 is arranged on a rear surface which is a surface different from the front surface of the semiconductor substrate 111 and irradiated with incident light. The imaging element 1 having such a configuration is referred to as a rear surface irradiation type imaging element. Furthermore, the imaging element 1 in FIG. 9 is different from the imaging element 1 illustrated in FIG. 3 in that a support substrate 141 is arranged to be adjacent to the wiring region 121 and the concave portion 149 is formed in the support substrate 141.

The support substrate 141 is a substrate supporting the semiconductor substrate 111 and the wiring region 121. The support substrate 141 enhances strength of the semiconductor substrate 111 or the like in a manufacturing process of the imaging element 1. The support substrate 141 can be, for example, a semiconductor or glass substrate. Note that the concave portion 149 is arranged in the support substrate 141 in FIG. 9. The concave portion 149 can be formed by etching the support substrate 141.

A method of manufacturing the imaging element 1 in FIG. 9 will be described. First, the semiconductor element such as the photoelectric conversion unit, the pixel circuit, or the like is formed on the semiconductor substrate 111 to form the wiring region 121 on the front surface of the semiconductor substrate 111. Next, the support substrate 141 is attached to be adjacent to the wiring region 121. Next, the top and bottom of the semiconductor substrate 111 are inverted, and the semiconductor substrate 111 is ground and thinned. The thinning can be performed by, for example, chemical mechanical polishing (CMP). Next, the color filter and the on-chip lens 101 are arranged on the front surface of the semiconductor substrate 111. Next, the concave portion 149 is formed in the support substrate 141, and the curve forming portion 160 and the curve holding portion 150 are sequentially arranged in the support substrate 141.

Note that an embedded layer that is easily released can also be formed on the semiconductor substrate 111 before the wiring region 121 is arranged. When the semiconductor substrate 111 is thinned, the rear surface of the semiconductor substrate 111 is peeled off at a part of the embedded layer. Thereafter, the peeled surface is ground and thinned, such that the grinding of the semiconductor substrate 111 can be simplified.

Since other configurations of the imaging element 1 are similar to the configurations of the imaging element 1 described in the first embodiment of the present disclosure, the description thereof is omitted.

As described above, the imaging element 1 of the second embodiment of the present disclosure is the rear surface irradiation type imaging element, the concave portion 149 is formed in the support substrate 141, and the curve forming portion 160 and the curve holding portion 150 are arranged in the support substrate 141. Therefore, the manufacturing process of the imaging element 1 adopting the rear surface irradiation type imaging element can be simplified.

### 3. Third Embodiment

The imaging element 1 of the second embodiment described above includes a single semiconductor substrate 111. Meanwhile, an imaging element 1 of a third embodiment of the present disclosure is different from the second embodiment described above in that a plurality of semiconductor substrates is attached.

[Configuration of Cross Section of Imaging Element]

FIG. 10 is a cross-sectional view illustrating a configuration example of the imaging element according to the third embodiment of the present disclosure. The imaging element 1 in FIG. 10 is different from the imaging element 1 illustrated in FIG. 9 in that a semiconductor substrate 112 and a wiring region 122 are arranged instead of the support substrate 141 and the concave portion 149 is formed in the semiconductor substrate 112.

The imaging element 1 in FIG. 10 is configured by attaching the semiconductor substrate 111 on which the pixel array unit 10 is formed and the semiconductor substrate 112 with the wiring region 121 and the wiring region 122 interposed between the semiconductor substrate 111 and the semiconductor substrate 112. For example, the column signal processing unit 30 illustrated in FIG. 1 can be arranged on the semiconductor substrate 112. The pixel circuit arranged on the semiconductor substrate 111 is operated at a relatively low speed while handling the analog image signal. On the other hand, an analog-digital conversion unit that converts the analog image signal to the digital image signal is arranged in the column signal processing unit 30, and the pixel circuit is operated at a relatively high speed. Therefore, these circuits are formed on different substrates, such that an optimum process can be selected. The wiring region 121 of the semiconductor substrate 111 and the wiring region 122 of the semiconductor substrate 112 are attached to each other.

A known technology can be applied in the attachment. Specifically, metal contact portions including Cu or the like are formed on surfaces on which the wiring region 121 and the wiring region 122 are attached, and the metal contact portions are bonded to each other when performing the attachment. Therefore, the wiring regions of the semiconductor substrate 111 and the semiconductor substrate 112 can be mechanically and electrically connected to each other.

As described above, the concave portion 149 is arranged on a rear surface of the semiconductor chip. In the imaging element 1 in FIG. 10, the concave portion 149 is formed in the semiconductor substrate 112. The curve forming portion 160 and the curve holding portion 150 are further arranged in the concave portion 149, and the curved portion 19 is formed and held.

Note that the configuration of the imaging element 1 is not limited to the example. For example, three or more semiconductor substrates can be attached to each other.

Since other configurations of the imaging element 1 are similar to the configurations of the imaging element 1 described in the first embodiment of the present disclosure, the description thereof is omitted.

As described above, in the imaging element 1 of the third embodiment of the present disclosure, the plurality of semiconductor substrates is attached, and the concave portion 149 is formed in the semiconductor substrate arranged at an end surface of the rear surface. Therefore, in the imaging element 1 in which the plurality of semiconductor substrates is attached, the curved portion 19 can be formed.

### 4. Fourth Embodiment

In the imaging element 1 of the third embodiment described above, the concave portion 149 is formed by etching the semiconductor substrate 112. Meanwhile, an imaging element 1 of a fourth embodiment of the present disclosure is different from the third embodiment described above in that an etching prevention layer that prevents etching is arranged.

[Configuration of Cross Section of Imaging Element]

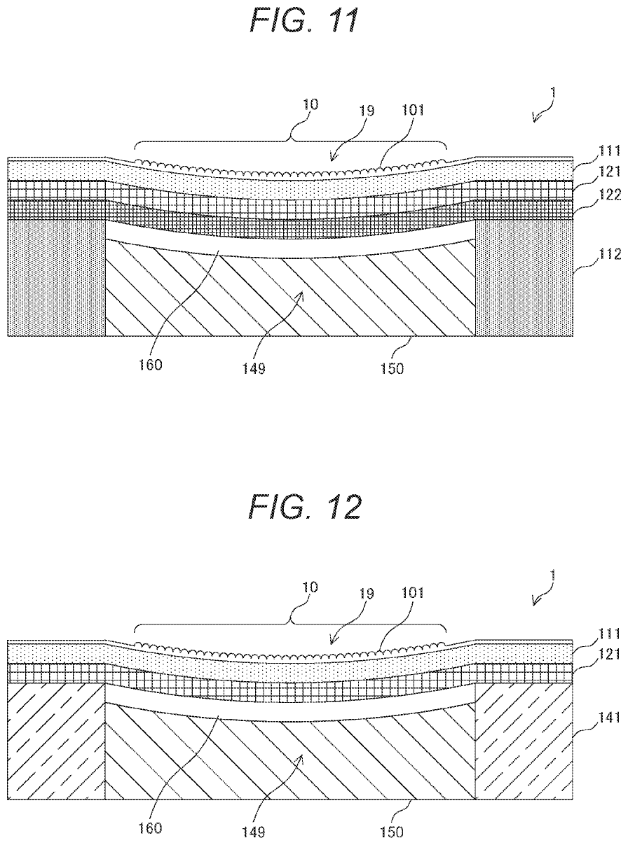

FIG. 11 is a cross-sectional view illustrating a configuration example of the imaging element according to the fourth embodiment of the present disclosure. The imaging element 1 in FIG. 11 is different from the imaging element 1 illustrated in FIG. 10 in that the concave portion 149 is arranged to be adjacent to the wiring region 122. That is, in the imaging element 1 in FIG. 11, the wiring region 122 is used as the etching prevention layer of the semiconductor substrate 112, and etching of the semiconductor substrate 112 is performed up to an interface with the wiring region 122.

The wiring region 122 in FIG. 11 stops the etching when forming the concave portion 149. Since the etching of the semiconductor substrate 112 is stopped by the wiring region 122, management of the amount of etching can be omitted, and the manufacturing process of the imaging element 1 can be simplified. Thereafter, the curve forming portion 160 is formed to be adjacent to the wiring region 122.

[Another Configuration of Cross Section of Imaging Element]

FIG. 12 is a cross-sectional view illustrating another configuration example of the imaging element according to the fourth embodiment of the present disclosure. FIG. 12 illustrates an example in a case where the support substrate 141 is arranged instead of the semiconductor substrate 112 and the wiring region 122. In the imaging element 1 in FIG. 12, the wiring region 121 can be used as the etching prevention layer.

Note that each of the wiring region 122 in FIG. 11 and the wiring region 121 in FIG. 12 is an example of the etching prevention layer described in the claims.

Since other configurations of the imaging element 1 are similar to the configurations of the imaging element 1 described in the first embodiment of the present disclosure, the description thereof is omitted.

As described above, in the imaging element 1 of the fourth embodiment of the present disclosure, each of the wiring regions 122 and 121 is used as the etching prevention layer, such that the amount of etching can be controlled in the etching of the semiconductor substrate 112 and the support substrate 141. Therefore, the manufacturing process of the imaging element 1 can be simplified.

### 5. Fifth Embodiment

In the imaging element 1 of the first embodiment described above, a rear surface of the curve holding portion 150 is released. Meanwhile, an imaging element 1 of a fifth embodiment of the present disclosure is different from the first embodiment described above in that a lid is arranged on the rear surface of the curve holding portion 150.

[Configuration of Cross Section of Imaging Element]

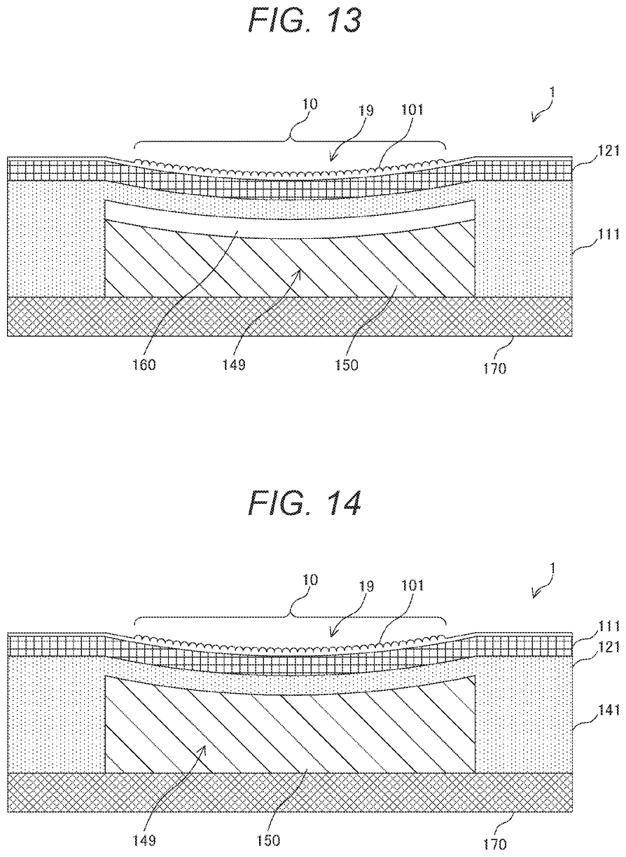

FIG. 13 is a cross-sectional view illustrating a configuration example of the imaging element according to the fifth embodiment of the present disclosure. The imaging element 1 in FIG. 13 is different from the imaging element 1 illustrated in FIG. 3 in that a lid 170 is arranged.

The lid 170 in FIG. 13 limits shrinkage of the curve holding portion 150. Specifically, the shrinkage of the rear surface of the curve holding portion 150 is limited by arranging the lid 170. Therefore, the amount of shrinkage in the vicinity of the curve forming portion 160 can be increased. Therefore, the curved portion 19 can be easily formed. An inorganic substrate including a metal, Si, SiO₂, or the like or an organic substrate including a resin or the like can be used for the lid 170. Note that the lid 170 can be arranged by, for example, arranging a liquid curve holding portion 150 in the concave portion 149 while adjusting an application amount, and then placing the lid 170 on the rear surfaces of the semiconductor substrate 111 and the curve holding portion 150. Furthermore, for example, the lid 170 can be adhered to the semiconductor substrate 111 before the application of the curve holding portion 150, and the liquid curve holding portion 150 can be applied through an opening formed in the lid 170. For example, an ultraviolet curing adhesive can be used as the adhesive. Furthermore, the liquid curve holding portion 150 can be subjected to vacuum defoaming through the opening.

Since other configurations of the imaging element 1 are similar to the configurations of the imaging element 1 described in the first embodiment of the present disclosure, the description thereof is omitted.

As described above, in the imaging element 1 of the fifth embodiment of the present disclosure, the lid 170 is arranged, such that the shrinkage of the rear surface of the curve holding portion 150 is limited to increase the amount of shrinkage in the vicinity of the curve forming portion 160. Therefore, the curved portion 19 can be easily formed.

### 6. Sixth Embodiment

In the imaging element 1 of the first embodiment described above, the curved portion 19 is formed by the curve forming portion 160. Meanwhile, an imaging element 1 of a sixth embodiment of the present disclosure is different from the first embodiment described above in that the curve forming portion 160 is omitted.

[Configuration of Cross Section of Imaging Element]

FIG. 14 is a cross-sectional view illustrating a configuration example of the imaging element according to the sixth embodiment of the present disclosure. The imaging element 1 in FIG. 14 is different from the imaging element 1 illustrated in FIG. 3 in that the curve forming portion 160 is omitted.

In the imaging element 1 in FIG. 14, only the curve holding portion 150 is arranged in the concave portion 149 of the semiconductor substrate 111. A resin having a curing shrink property is used for the curve holding portion 150, such that the curve forming portion 160 can be omitted. Furthermore, the lid 170 is further arranged, such that the amount of shrinkage of the curve holding portion 150 in the vicinity of the wiring region 121 can be increased.

Since other configurations of the imaging element 1 are similar to the configurations of the imaging element 1 described in the first embodiment of the present disclosure, the description thereof is omitted.

As described above, in the imaging element 1 of the sixth embodiment of the present disclosure, the curved portion 19 is formed on the imaging chip by the curve holding portion 150. Therefore, the curve forming portion 160 can be omitted, and the manufacturing process of the imaging element 1 can be simplified.

### 7. Seventh Embodiment

In the imaging element 1 of the first embodiment described above, the curve holding portion 150 including the resin is used. Meanwhile, an imaging element 1 of a seventh embodiment of the present disclosure is different from the first embodiment described above in that a holding base body including a metal or the like is adhered to the semiconductor substrate 111 in which the curved portion 19 is formed.

[Configuration of Cross Section of Imaging Element]

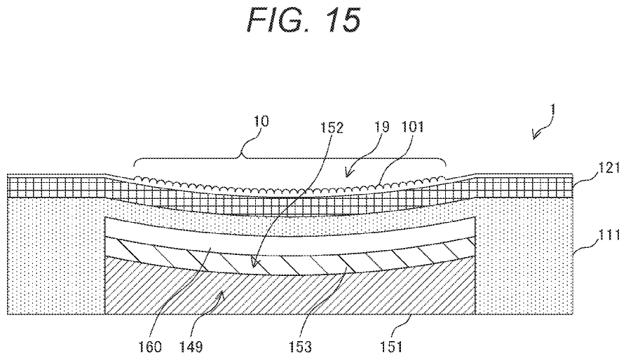

FIG. 15 is a cross-sectional view illustrating a configuration example of the imaging element according to the seventh embodiment of the present disclosure. The imaging element 1 in FIG. 15 is different from the imaging element 1 illustrated in FIG. 3 in that a holding base body 151 and an adhesive portion 153 are arranged instead of the curve holding portion 150.

The holding base body 151 is arranged in the concave portion 149 and holds the curved portion 19 of the semiconductor substrate 111. A second concave portion 152 fitted into the curved portion 19 is formed in the holding base body 151, and the holding base body 151 is adhered to the curve forming portion 160 by the adhesive portion 153. The holding base body 151 can include, for example, a metal, a semiconductor, glass, and a resin. The holding base body 151 is arranged in the concave portion 149, such that rigidity of the imaging element 1 can be enhanced.

The curve forming portion 160 and the holding base body 151 are adhered to each other by the adhesive portion 153. An adhesive including a thermosetting resin, a thermoplastic resin, or the like can be used for the adhesive portion 153.

The holding base body 151 is adhered to the curve forming portion 160 as follows. First, the second concave portion 152 fitted into a shape of the curved portion 19 to be expected is formed in the holding base body 151. Next, the adhesive portion 153 is applied to the second concave portion 152 and fitted into the concave portion 149, such that the adhesive portion 153 applied to the holding base body 151 is arranged to be adjacent to the curve forming portion 160. Thereafter, the imaging element 1 is heated, such that the curved portion 19 is formed on the semiconductor substrate 111 by the curve forming portion 160, and the adhesive portion 153 is cured. Therefore, the semiconductor substrate 111 on which the curved portion 19 is formed and the holding base body 151 can be adhered to each other. Note that the adhesive portion 153 is applied to the curve forming portion 160, and then, the holding base body 151 can be arranged in the concave portion 149 and heated.

Furthermore, the imaging element 1 is heated, such that the holding base body 151 to which the adhesive portion 153 is applied can be arranged in the concave portion 149 of the semiconductor substrate 111 on which the curved portion 19 is formed, and the holding base body 151 can be adhered to the curve forming portion 160.

Since other configurations of the imaging element 1 are similar to the configurations of the imaging element 1 described in the first embodiment of the present disclosure, the description thereof is omitted.

As described above, in the imaging element 1 of the seventh embodiment of the present disclosure, each of the holding base body 151 and the adhesive portion 153 is used as the curve holding portion 150, such that rigidity of the imaging element 1 can be enhanced.

Finally, the description of each of the embodiments described above is an example of the present disclosure, and the present disclosure is not limited to the embodiments described above. Therefore, it is needless to say that various modifications depending on a design or the like are possible in addition to each embodiment described above without departing from the technical idea according to the present disclosure.

Note that the present technology can be configured as follows.

(1) An imaging element including:

an imaging chip that includes a semiconductor chip having a rear surface on which a concave portion is formed, the rear surface being a surface different from a light receiving surface that receives light from a subject;

a curve forming portion that is arranged in the concave portion and forms a curved portion by curving the imaging chip at a bottom of the concave portion; and

a curve holding portion that holds the formed curved portion.

(2) The imaging element according to (1), in which the curve forming portion has a linear expansion coefficient higher than that of the imaging chip and is heated to form the curved portion.

(3) The imaging element according to (2), in which the curve forming portion includes a metal.

(4) The imaging element according to (2), in which the curve holding portion includes a thermosetting resin. (5) The imaging element according to (4), in which the curve forming portion forms the curved portion when the curve holding portion is cured.

(6) The imaging element according to (4), in which the curve holding portion includes a thermosetting resin that shrinks when cured.

(7) The imaging element according to (6), further including a lid that is arranged to be adjacent to the curve holding portion and limits shrinkage of the curve holding portion in the vicinity of an opening of the concave portion.

(8) The imaging element according to any one of (1) to (7), in which the curve holding portion includes a holding base body in which a second concave portion fitted into the curved portion is arranged and an adhesive portion arranged between the holding base body and the curve forming portion.

(9) The imaging element according to any one of (1) to (8), further including an etching prevention layer that is arranged at a bottom of the concave portion in the semiconductor chip and prevents etching of the semiconductor chip.

(10) A method of manufacturing an imaging element, the method including:

a step of forming a concave portion on a rear surface of an imaging chip that includes a semiconductor chip, the rear surface being a surface different from a light receiving surface that receives light from a subject;

a step of forming a curved portion by a curve forming portion that forms the curved portion by curving the imaging chip at a bottom of the concave portion; and

a step of holding the curved portion by a curve holding portion that holds the formed curved portion.

### REFERENCE SIGNS LIST

1 Imaging element
4 Circuit board
5 Actuator
6 Imaging lens
7 Protective glass
10 Pixel array unit
19 Curved portion
11, 12, 41, 42 Signal line
20 Vertical driving unit
30 Column signal processing unit
40 Control unit
100 Pixel
101 On-chip lens
111, 112 Semiconductor substrate
121, 122 Wiring region
141 Support substrate
149 Concave portion
151 Holding base body
152 Second concave portion
153 Adhesive portion
150 Curve holding portion
160 Curve forming portion
170 Lid

1. An imaging element comprising:
an imaging chip that includes a semiconductor chip having a rear surface on which a concave portion is formed, the rear surface being a surface different from a light receiving surface that receives light from a subject;
a curve forming portion that is arranged in the concave portion and forms a curved portion by curving the imaging chip at a bottom of the concave portion; and
a curve holding portion that holds the formed curved portion.

2. The imaging element according to claim 1, wherein the curve forming portion has a linear expansion coefficient higher than that of the imaging chip and is heated to form the curved portion.

3. The imaging element according to claim 2, wherein the curve forming portion includes a metal.

4. The imaging element according to claim 2, wherein the curve holding portion includes a thermosetting resin.

5. The imaging element according to claim 4, wherein the curve forming portion forms the curved portion when the curve holding portion is cured.

6. The imaging element according to claim 4, wherein the curve holding portion includes a thermosetting resin that shrinks when cured.

7. The imaging element according to claim 6, further comprising a lid that is arranged to be adjacent to the curve holding portion and limits shrinkage of the curve holding portion in a vicinity of an opening of the concave portion.

8. The imaging element according to claim 1, wherein the curve holding portion includes a holding base body in which a second concave portion fitted into the curved portion is arranged and an adhesive portion arranged between the holding base body and the curve forming portion.

9. The imaging element according to claim 1, further comprising an etching prevention layer that is arranged at a bottom of the concave portion in the semiconductor chip and prevents etching of the semiconductor chip.

10. A method of manufacturing an imaging element, the method comprising:
a step of forming a concave portion on a rear surface of an imaging chip that includes a semiconductor chip, the rear surface being a surface different from a light receiving surface that receives light from a subject;
a step of forming a curved portion by a curve forming portion that forms the curved portion by curving the imaging chip at a bottom of the concave portion; and
a step of holding the curved portion by a curve holding portion that holds the formed curved portion.
